(19) United States
(12) Patent Application Publication
(10) Pub. No.: US 2026/0288179 A1
(43) Pub. Date: Sep. 24, 2026

(54) CURRENT DRIVER DEVICE

(71) Applicants: Kabushiki Kaisha Toshiba, Kawasaki-shi (JP); Toshiba Electronic Devices & Storage Corporation, Kawasaki-shi (JP)

(72) Inventor: Maho KUWAHARA, Meguro Tokyo (JP)

(21) Appl. No.: 19/364,269

(22) Filed: Oct. 21, 2025

(30) Foreign Application Priority Data
Mar. 19, 2025 (JP) 2025-045612

(51) Int. Cl. G05F 1/46; G01R 17/04

(52) U.S. Cl. CPC G05F 1/468; G01R 17/04

(57) ABSTRACT

The current driver device, according to embodiment, includes: a current driver circuit that has an output section connected to the output terminal, that is driven by a power supply voltage and outputs an output AC current from the output section in response to an input AC voltage; a charging circuit that charges the capacitor of the load and sets the voltage of the output terminal to an initial bias voltage; a drive current adjustment circuit that detects a monitor voltage, which is an AC voltage generated in the output section of the current driver circuit, and that applies an adjustment DC current to an adjustment terminal between the output section of the current driver circuit and the output terminal based on the detection result of the monitor voltage; and a control circuit that controls the current driver circuit, the charging circuit, and the drive current adjustment circuit.

### CROSS-REFERENCETORELATEDAPPLICATIONS

This application is based upon and claims the benefit of priority from the prior Japanese Patent Application No. 2025-045612, filed on Mar. 19, 2025 the entire contents of which are incorporated herein by reference.

### FIELD

This embodiment relates to a current driver device.

### BACKGROUND

Conventionally, there are current driver devices for AC driving loads that include capacitors such as LC loads. In such conventional current driver devices, it is necessary to control the operating point voltage of the current driver device within a specified operating range.

### BRIEF DESCRIPTION OF THE DRAWINGS

FIG. 1 is a diagram showing an example of the configuration of a current driver device according to a first embodiment.

FIG. 2 is a diagram showing an example of waveforms of a monitor voltage (operating point voltage), which is an AC voltage generated in a current driver circuit of the current driver device shown in FIG. 1, a peak detection voltage, and a bottom detection voltage of the monitor voltage.

FIG. 3 is a diagram showing an example of waveforms of a drive current output by the current driver device shown in FIG. 1, an adjustment DC current for adjusting the drive current, and an operating point voltage of an AC voltage generated in the current driver circuit.

FIG. 4 is a diagram showing an example of the configuration of a current driver device according to a second embodiment.

FIG. 5 is a diagram showing an example of the relationship between a drive period during which the current driver circuit of the current driver device shown in FIG. 4 is driven and a stop period during which it is stopped, and the operation of a drive current adjustment circuit.

FIG. 6 is a diagram showing an example of the relationship between a monitor voltage V1 and a reference voltage, and voltage comparison result information, during a drive period H1 during which the current driver circuit of the current driver device shown in FIG. 5 is driven.

### DETAILED DESCRIPTION

One embodiment aims to provide a current driver device that can suppress a decrease in the drive current that drives a load including a capacitor while controlling the operating point voltage of a current driver circuit within a predetermined operating range.

A current driver device, according to one embodiment, for supplying a preset drive current to a load including a capacitor via an output terminal, includes:

a current driver circuit that has an output section connected to the output terminal, that is driven by a power supply voltage and outputs an output AC current from the output section in response to an input AC voltage;

a charging circuit that charges the capacitor of the load and sets the voltage of the output terminal to an initial bias voltage;

a drive current adjustment circuit that detects a monitor voltage, which is an AC voltage generated in the output section of the current driver circuit, and that applies an adjustment DC current to an adjustment terminal between the output section of the current driver circuit and the output terminal based on the detection result of the monitor voltage; and

a control circuit that controls the current driver circuit, the charging circuit, and the drive current adjustment circuit.

The current driver device according to the embodiments will be described in detail below with reference to the accompanying drawings. Note that the present invention is not limited to these embodiments.

### FIRST EMBODIMENT

### Current driver device

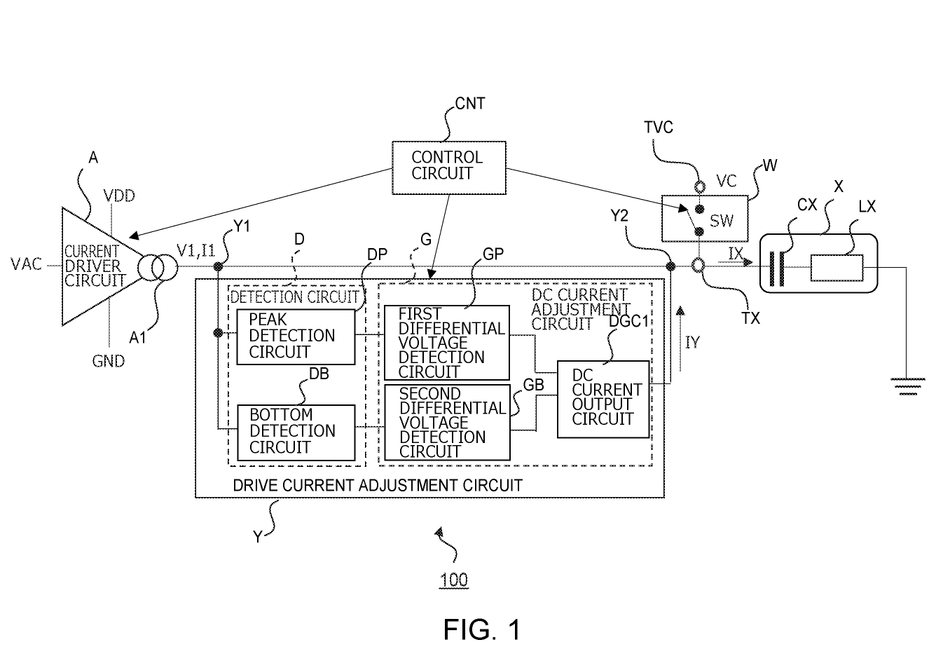

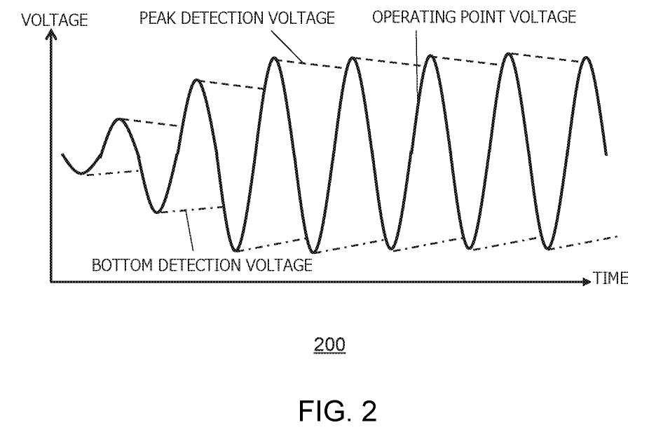

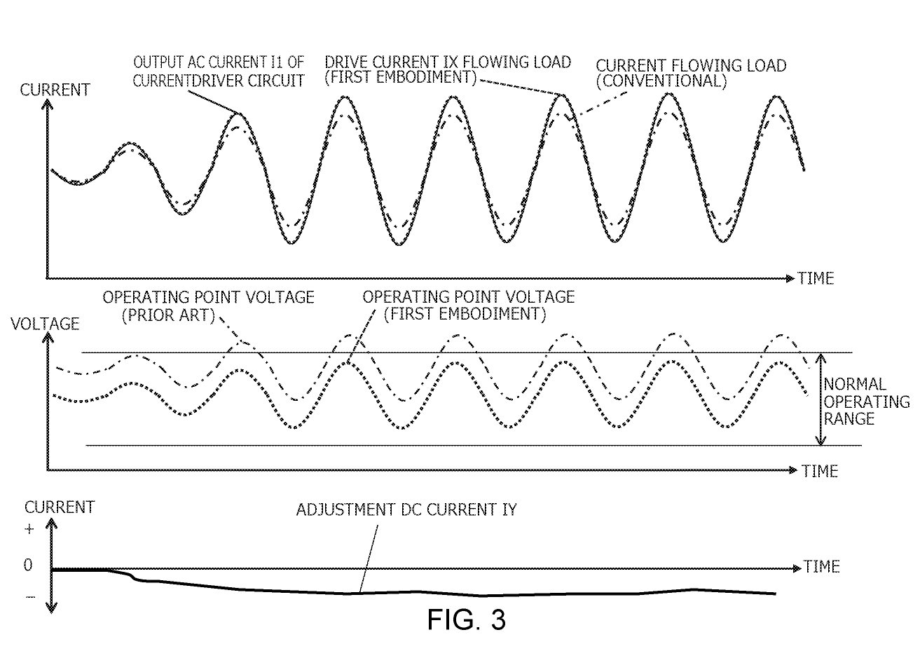

FIG. 1 is a diagram showing an example of the configuration of a current driver device according to the first embodiment. FIG. 2 is a diagram showing an example of the waveforms of a monitor voltage (operating point voltage), which is an AC voltage generated in the current driver circuit of the current driver device shown in FIG. 1, and a peak detection voltage and a bottom detection voltage of the monitor voltage. FIG. 3 is a diagram showing an example of the waveforms of a drive current output by the current driver device shown in FIG. 1, an adjustment DC current for adjusting the drive current, and an operating point voltage of an AC voltage generated in the current driver circuit.

The current driver device 100 according to the first embodiment is configured to supply a preset driving current IX via an output terminal TX to a load X including a capacitor CX, as shown in FIG. 1, for example.

In the example shown in FIG. 1, the load X includes a capacitor CX and an inductor LX connected in series to the capacitor CX. In this embodiment, it is assumed that the load X includes at least the capacitor CX.

The current driver device 100 according to the first embodiment includes, for example, a current driver circuit A, a charging circuit W, a drive current adjustment circuit Y, and a control circuit CNT, as shown in FIG. 1.

Below, these configurations of the current driver device 100 relating to the first embodiment will be described in detail.

### Current driver circuit

The current driver circuit A is connected between the power supply and ground, and has an output section A1 connected to the output terminal TX. During the driving period, the current driver circuit A is driven by the power supply voltage VDD, and outputs an output AC current I1 from the output section A1 in response to the input AC voltage VAC.

This current driver circuit A has, for example, a general configuration and has the general characteristics that the output AC current I1 is constant and does not depend on load variations or temperature power supply, and the phase of the output AC current I1 is constant and does not depend on load variations.

### Charging circuit

The charging circuit W charges the capacitor CX of the load X and sets the voltage of the output terminal TX to an initial bias voltage.

This charging circuit W includes a switch circuit SW controlled by a control circuit CNT, as shown in FIG. 1, for example.

This switch circuit SW is connected, for example, as shown in FIG. 1, between a charging terminal TVC to which a charging voltage VC is applied and an output terminal TX.

The switch circuit SW brings the charging terminal TVC and the output terminal TX into a conductive state when the switch circuit SW is turned on, or into a cut-off state when the switch circuit SW is turned off.

For example, when the charging circuit W is turned on, it brings the charging terminal TVC and the output terminal TX into a conductive state, charges the capacitor CX of the load X, and sets the voltage of the output terminal TX to an initial bias voltage (here, the charging voltage VC).

It is noted that the charging voltage VC is, for example, the midpoint voltage between the power supply voltage VDD and the ground voltage GND.

It is noted that the configuration of charging circuit W shown in FIG. 1 is just one example, and it may be configured with other configurations that can perform similar functions.

### Drive current adjustment circuit

The drive current adjustment circuit Y detects the monitor voltage V1, which is an AC voltage generated in the output section A1 of the current driver circuit A, and applies an adjustment DC current IY to the adjustment terminal Y2 between the output section A1 of the current driver circuit A and the output terminal TX based on the detection result of the monitor voltage V1.

Therefore, the drive current IX is the sum of the output AC current I1 output by the current driver circuit A and the adjustment DC current IY output by the drive current adjustment circuit Y. The adjustment DC current IY output by the drive current adjustment circuit Y is set in the range of positive to negative current values.

This drive current adjustment circuit Y includes, for example, a detection circuit D and a DC current adjustment circuit G, as shown in FIG. 1.

### Detection circuit

Detection circuit D detects the waveform of monitor voltage V1, which is an AC voltage (operating point voltage) generated in output section A1 of current driver circuit A, and outputs the detection result of the waveform of monitor voltage V1 (for example, the peak detection voltage and bottom detection voltage shown in FIG. 2).

The waveform of the monitor voltage (operating point voltage) V1 of the AC voltage generated by the AC current output by current driver circuit A in response to input AC voltage VAC will fluctuate. For this reason, for example, as shown in FIG. 2, detection circuit D performs peak detection processing and bottom detection processing to detect the fluctuating voltage.

That is, this detection circuit D includes, for example, a peak detection circuit DP and a bottom detection circuit DB, as shown in FIG. 1.

The peak detection circuit DP is configured to detect the peak of the monitor voltage (operating point voltage) V1 output from the output section A1 via the monitor terminal Y1 connected to the output section A1 of the current driver circuit A.

For example, this peak detection circuit DP detects the monitor voltage (operating point voltage) V1 output from the output section A1 via the monitor terminal Y1, and detects a peak detection voltage (FIG. 2) corresponding to the peak of the waveform of the monitor voltage V1.

The bottom detection circuit DB detects the bottom of the monitor voltage (operating point voltage) V1 output from the output section A1 via a monitor terminal Y1 connected to the output section A1 of the current driver circuit A.

For example, the bottom detection circuit DB detects the monitor voltage (operating point voltage) V1 output from the output section A1 via the monitor terminal Y1, thereby detecting a bottom detection voltage (FIG. 2) corresponding to the bottom of the waveform of the monitor voltage V1.

### DC current adjustment circuit

The DC current adjustment circuit G applies a positive or negative adjustment DC current IY to the adjustment terminal Y2 between the output section A1 and the output terminal TX of the current driver circuit A based on the result of comparing the detection result of the waveform of the monitor voltage V1 output by the detection circuit D with the power supply voltage VDD and/or the ground voltage GND.

In this first embodiment, the DC current adjustment circuit G includes, for example, a first differential voltage detection circuit GP, a second differential voltage detection circuit GB, and a DC current output circuit DGC1, as shown in FIG. 1.

### First differential voltage detection circuit

The first differential voltage detection circuit GP receives information on the peak detection voltage detected by the peak detection circuit DP and the power supply voltage VDD (for example, the peak detection voltage and the power supply voltage VDD).

The first differential voltage detection circuit GP detects a first differential voltage, which is the difference between the peak detection voltage detected by the peak detection circuit DP and the power supply voltage VDD, and outputs information related to this first differential voltage (for example, a voltage corresponding to the first differential voltage).

### Second differential voltage detection circuit

The second differential voltage detection circuit GB receives information on the bottom detection voltage and the ground voltage GND detected by the bottom detection circuit DB (for example, the bottom detection voltage and the ground voltage GND).

The second differential voltage detection circuit GB detects a second differential voltage, which is the difference between the bottom detection voltage detected by the bottom detection circuit DB and the ground voltage GND, and outputs information related to this second differential voltage (for example, a voltage corresponding to the second differential voltage).

### DC current output circuit

The DC current output circuit DGC1 controls the adjustment DC current IY and outputs it to the adjustment terminal Y2 so that the difference between the first differential voltage and the second differential voltage approaches a preset reference value.

It is noted that, for example, the reference value may be zero. In this case, the DC current output circuit DCG1 controls and outputs the adjustment DC current IY so that the first differential voltage and the second differential voltage are equal.

It is noted that the configuration of the drive current adjustment circuit Y shown in FIG. 1 as described above is just one example, and the drive current adjustment circuit Y may be configured in another manner that can perform the same function as the drive current adjustment circuit Y.

### Control Circuit

The control circuit CNT also controls the current driver circuit A, the charging circuit W, and the drive current adjustment circuit Y.

For example, during the suspension period before the current driver circuit A starts to operate, the control circuit CNT turns on the switch circuit SW to charge the capacitor CX of the load X with the charging voltage VC up to the initial bias voltage.

As mentioned above, the charging voltage VC is the midpoint voltage between the power supply voltage VDD and the ground voltage GND.

The control circuit CNT charges the capacitor CX of the load X with the charging voltage VC up to the initial bias voltage, then turns off the switch circuit SW, and starts driving the current driver circuit A during the drive period.

### Operation of the current driver device

Next, an example of the operation of the current driver device 100 having the above configuration will be described.

For example, during the suspension period before the current driver circuit A starts to operate, the control circuit CNT turns on the switch circuit SW to charge the capacitor CX of the load X with the charging voltage VC up to the initial bias voltage.

Then, the control circuit CNT charges the capacitor CX of the load X with the charging voltage VC up to the initial bias voltage, then turns off the switch circuit SW, and starts driving the current driver circuit A in the drive period.

During the drive period, the drive current adjustment circuit Y detects the monitor voltage V1, which is an AC voltage generated in the output section A1 of the current driver circuit A, and applies an adjustment DC current IY to the adjustment terminal Y2 between the output section A1 and the output terminal TX of the current driver circuit A based on the detection result of the monitor voltage V1.

For example, detection circuit D of drive current adjustment circuit Y detects the waveform of monitor voltage V1, which is the AC voltage (operating point voltage) generated in output section A1 of current driver circuit A, and outputs the detection result of the waveform of monitor voltage V1 (for example, the peak detection voltage and bottom detection voltage shown in FIG. 2).

In this case, the peak detection circuit DP of detection circuit D detects the peak of the monitor voltage (operating point voltage) V1 output from output section A1 via the monitor terminal Y1 connected to output section A1 of current driver circuit A.

For example, this peak detection circuit DP detects the monitor voltage (operating point voltage) V1 output from the output section A1 via the monitor terminal Y1, and detects the peak detection voltage (FIG. 2) corresponding to the peak of the waveform of the monitor voltage V1.

Furthermore, the bottom detection circuit DB of detection circuit D detects the bottom of the monitor voltage (operating point voltage) V1 output from output section A1 via a monitor terminal Y1 connected to output section A1 of current driver circuit A.

For example, the bottom detection circuit DB detects the monitor voltage (operating point voltage) V1 output from the output section A1 via the monitor terminal Y1, and detects the bottom detection voltage (FIG. 2) corresponding to the bottom of the waveform of the monitor voltage V1.

Then, the DC current adjustment circuit G of the drive current adjustment circuit Y applies a positive or negative adjustment DC current IY to the adjustment terminal Y2 between the output section A1 and the output terminal TX of the current driver circuit A, based on the result of comparing the detection result of the waveform of the monitor voltage V1 output by the detection circuit D with the power supply voltage VDD and/or the ground voltage GND.

For example, the first differential voltage detection circuit GP of the DC current adjustment circuit G detects a first differential voltage, which is the difference between the peak detection voltage detected by the peak detection circuit DP and the power supply voltage VDD, and outputs information (for example, a voltage corresponding to the first differential voltage) related to this first differential voltage.

Furthermore, the second differential voltage detection circuit GB of the DC current adjustment circuit G detects a second differential voltage, which is the difference between the bottom detection voltage detected by this bottom detection circuit DB and the ground voltage GND, and outputs information (for example, a voltage corresponding to the second differential voltage) related to this second differential voltage.

Then, the DC current output circuit DGC1 of the DC current adjustment circuit G controls the adjustment DC current IY and outputs it to the adjustment terminal Y2 so that the difference between the first differential voltage and the second differential voltage approaches a preset reference value (FIG. 3).

It is noted that, for example, the reference value may be zero. In this case, the DC current output circuit DCG1 controls and outputs the adjustment DC current IY so that the first differential voltage and the second differential voltage are equal.

By the operation of the current driver device 100 in the above drive period, for example, as shown in FIG. 3, the operating point voltage of the current driver circuit A of the current driver device 100 can be controlled within a predetermined operating range (normal operating range), and the decrease in the drive current that drives the load including the capacitor can be suppressed.

In other words, according to the current driver device of the first embodiment, it is possible to suppress the decrease in the drive current that drives a load including a capacitor while controlling the operating point voltage of the current driver circuit within a predetermined operating range (a range in which the current driver circuit operates normally).

### SECOND EMBODIMENT

Here, in the first embodiment described above, an example of the configuration of a current driver device that executes analog signal processing has been explained. However, the configuration of this current driver device is not limited to this. Therefore, in this second embodiment, an example of the configuration of a current driver device that executes digital signal processing will be explained.

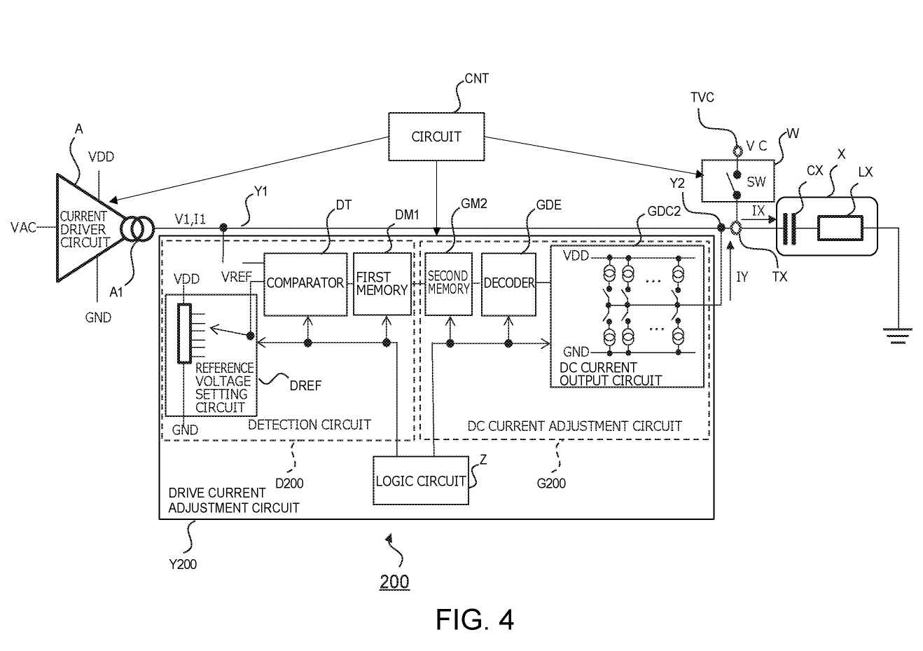

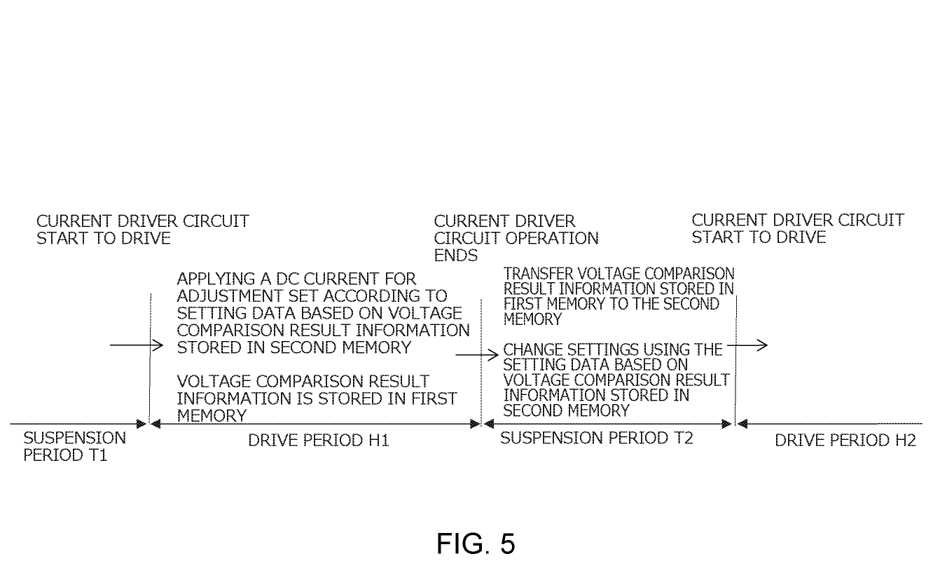

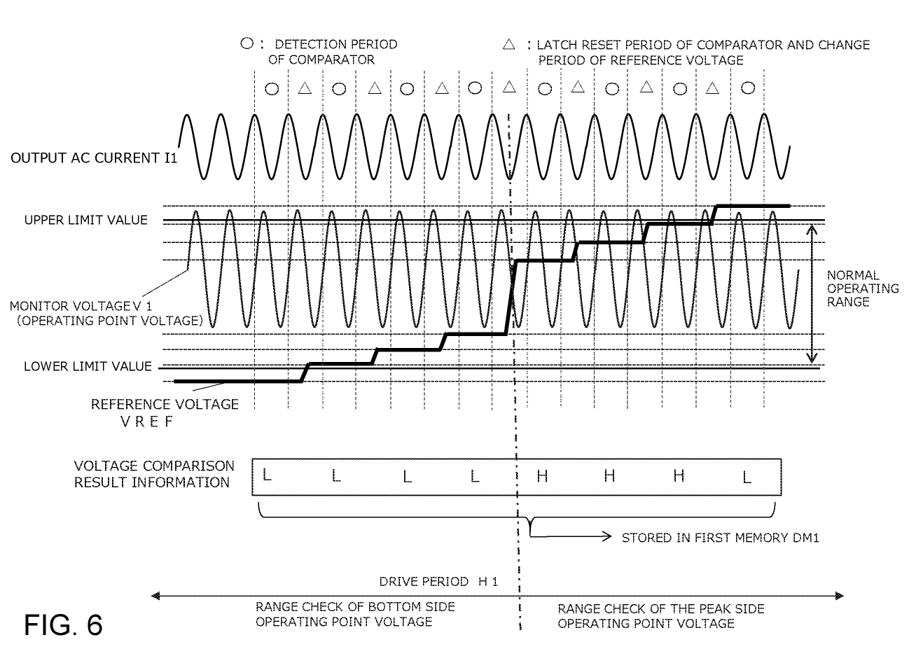

FIG. 4 is a diagram showing an example of the configuration of a current driver device according to the second embodiment. FIG. 5 is a diagram showing an example of the relationship between the drive period, the suspension period, and the operation of the drive current adjustment circuit. The drive period is a period that the current driver circuit of the current driver device shown in FIG. 4 is driven, and the suspension period is a period that the current driver circuit is stopped. FIG. 6 is a diagram showing an example of the relationship between the monitor voltage V1, the reference voltage, and the voltage comparison result information. The voltage comparison result information is information that is in the drive period H1 in which the current driver circuit of the current driver device shown in FIG. 5 is driven.

It is noted that in the following description of the current driver device according to the second embodiment, the description of the components having the same reference numerals as those in the first embodiment will be omitted.

For example, as shown in FIG. 4, the current driver device 200 according to the second embodiment is configured to supply a preset drive current IX via an output terminal TX to a load X including a capacitor CX.

The current driver device 200 according to the second embodiment includes, for example, a current driver circuit A, a charging circuit W, a drive current adjustment circuit Y 200, and a control circuit CNT, as shown in FIG. 1.

The configuration of the current driver device 200 relating to the second embodiment will now be described in detail.

### Drive current adjustment circuit

The drive current adjustment circuit 200Y detects the monitor voltage V1, which is an AC voltage generated in the output section A1 of the current driver circuit A, and applies an adjustment DC current IY to the adjustment terminal Y2 between the output section A1 and the output terminal TX of the current driver circuit A based on the detection result of the monitor voltage V1.

Therefore, the drive current IX is the sum of the output AC current I1 output by the current driver circuit A and the adjustment DC current IY output by the drive current adjustment circuit Y. The adjustment DC current IY output by the drive current adjustment circuit Y is set in the range of positive to negative current values.

This drive current adjustment circuit Y200 includes, for example, a detection circuit D200, a DC current adjustment circuit G200, and a logic circuit Z, as shown in FIG. 4.

Thus, the drive current adjustment circuit Y200 of the current driver device 200 according to the second embodiment further includes a logic circuit Z for performing digital signal processing, as compared to the drive current adjustment circuit Y of the current driver device 100 according to the first embodiment.

In other words, the configuration of the drive current adjustment circuit Y200 differs from that of the drive current adjustment circuit Y of the first embodiment, which performs analog signal processing, in that the drive current adjustment circuit Y200 performs digital signal processing.

### Detection Circuit

The detection circuit D200 detects the waveform of the monitor voltage V1, which is an AC voltage generated in the output section A1 of the current driver circuit A, and outputs the detection result of the waveform of the monitor voltage V1.

This detection circuit D200 includes, for example, a reference voltage setting circuit DREF, a comparator DT, and a first memory DM1, as shown in FIG. 4.

### Reference voltage setting circuit

The reference voltage setting circuit DREF sets one of multiple reference voltages VREF and outputs one of multiple reference voltages VREF.

For example, this reference voltage setting circuit DREF is designed to output a value of the reference voltage VREF that changes in stages.

In particular, the reference voltage setting circuit DREF generates and outputs the reference voltage VREF so that the value changes stepwise at time intervals longer than the period of the monitor voltage (operating point voltage) V1 (FIG. 6).

### Comparator

The comparator DT sequentially compares the reference voltage VREF output by the reference voltage setting circuit DREF with the monitor voltage V1, and outputs voltage comparison result information (FIG. 6) according to the comparison result.

### First memory

The first memory DM1 stores the voltage comparison result information output from the comparator DT and outputs the stored information.

The detection circuit D200 outputs (transfers) the voltage comparison result information stored in this first memory DM1 to the DC current adjustment circuit G200 as the detection result of the waveform of the monitor voltage V1.

### DC current adjustment circuit

The DC current adjustment circuit G200 applies a positive or negative adjustment DC current IY to the adjustment terminal Y2 between the output section A1 and the output terminal TX of the current driver circuit A based on the voltage comparison result information output by the detection circuit D.

In the second embodiment, the DC current adjustment circuit G200 includes, for example, a second memory GM2, a decoder GDE, and a DC current output circuit DGC2, as shown in FIG. 4.

### Second memory

The second memory GM2 is configured to store the voltage comparison result information transferred from the first memory DM1.

### Decoder

The decoder GDE decodes the voltage comparison result information stored in the second memory GM2 to obtain and output setting data for setting the value of the adjustment DC current IY.

### DC current output circuit

The DC current output circuit DGC2 sets the value of the adjustment DC current IY based on the setting data, and outputs the set value of the adjustment DC current IY to the adjustment terminal Y2.

### Logic circuit

The logic circuit Z controls the operation of the detection circuit D200 and the DC current adjustment circuit G200, for example, as shown in FIG. 4.

The logic circuit Z is configured to control the reference voltage setting circuit DREF, the comparator DT, the first memory DM1, and the second memory GM2, for example, in response to a control signal output from the control circuit CNT.

For example, in a drive period H1 (FIGS. 5 and 6) in which the current driver circuit A is driven, the logic circuit Z causes the decoder GDE to decode the voltage comparison result information stored in the second memory GM2 during the previous suspension period T1, thereby obtaining and outputting setting data for setting the value of the adjustment DC current IY.

Furthermore, in the drive period H1 (FIGS. 5 and 6), the logic circuit Z sets the value of the adjustment DC current IY in the DC current output circuit DGC2 based on the setting data, and outputs the set value of the adjustment DC current IY to the adjustment terminal Y2.

For example, as shown in FIGS. 5 and 6, in drive period H1, logic circuit Z causes reference voltage setting circuit DREF to output reference voltage VREF by changing the value of reference voltage VREF in stages.

Furthermore, for example, as shown in FIGS. 5 and 6, in the drive period H1, the logic circuit Z causes the comparator DT to sequentially compare the reference voltage VREF output by the reference voltage setting circuit DREF with the monitor voltage V1, and output voltage comparison result information (L: low level/H: high level) according to the comparison result.

For example, the comparator DT compares the reference voltage VREF with the monitor voltage V1, and when the monitor voltage V1 crosses the reference voltage VREF (V1 crosses VREF and transitions from a low voltage to a high voltage or from a high voltage to a low voltage), the comparator DT outputs voltage comparison result information (H: High level) according to the comparison result.

On the other hand, the comparator DT compares the reference voltage VREF with the monitor voltage V1, and if the monitor voltage V1 is always higher or lower than the reference voltage VREF during the detection period, the comparator DT outputs voltage comparison result information (L: Low level) according to the comparison result.

Here, in the example of FIG. 6, ○ indicates the detection period of the comparator DT, and △ indicates the latch reset period of the comparator DT and the change period of the reference voltage. The normal operating range of the current driver circuit A is defined by the preset upper and lower limits.

For example, as shown in FIG. 6, in drive period H1, the reference voltage setting circuit DREF outputs the reference voltage VREF so that the value of the reference voltage VREF increases stepwise.

In the example of FIG. 6, the comparator DT outputs voltage comparison result information (L, L, L, L) as a range check of the bottom side operating point voltage because the monitor voltage V1 is always higher than the reference voltage VREF during the drive period H1. Furthermore, the comparator DT outputs voltage comparison result information (H, H, H, L) as a range check of the peak side operating point voltage because the monitor voltage V1 changes from a higher state to a lower state than the reference voltage VREF during the drive period H1. The operating point state of the monitor voltage V1 can be known from the voltage comparison result information (L, L, L, L), which is the result of checking the bottom side operating point voltage, and the voltage comparison result information (H, H, H, L), which is the range check of the peak side operating point voltage.

Then, for example, as shown in FIGS. 5 and 6, during the drive period H1, the logic circuit Z stores the voltage comparison result information output from the comparator DT in the first memory DM1.

For example, as shown in FIG. 5, in a suspension period T2 following a drive period H1 in which the current driver circuit A is stopped, the logic circuit Z transfers the voltage comparison result information stored in the first memory DM1 from the first memory DM1 to the second memory GM2, and stores this voltage comparison result information in the second memory GM2 as voltage comparison result information to be used in the next drive period H2 following the suspension period T2.

It is noted that the current driver circuit A is not limited to being driven when supplying the drive current IX to the load X, and the logic circuit Z may operate the current driver circuit A exclusively for setting the value of the adjustment DC current IY.

When the current driver circuit A starts driving for the first time, the drive current adjustment circuit Y 200 (logic circuit Z) may be configured so that the adjustment DC current IY is set to an initial current value (e.g., zero) (the voltage comparison result information written in the second memory GM2 is set to a pre-defined initial value).

### Operation of the current driver device

Next, an example of the operation of the current driver device 200 having the above configuration will be described.

For example, as shown in FIG. 5, during the suspension period T1 before the current driver circuit A starts to drive, the control circuit CNT turns on the switch circuit SW to charge the capacitor CX of the load X with the charging voltage VC up to the initial bias voltage.

Then, the control circuit CNT charges the capacitor CX of the load X with the charging voltage VC up to the initial bias voltage, and then turns off the switch circuit SW, and starts driving the current driver circuit A in the drive period H1.

Then, the logic circuit Z controls the reference voltage setting circuit DREF, the comparator DT, the first memory DM1, and the second memory GM2, for example, in response to a control signal output from the control circuit CNT.

For example, in a drive period H1 (FIGS. 5 and 6) in which the current driver circuit A is operating, the logic circuit Z causes the decoder GDE to obtain and output setting data for setting the value of the adjustment DC current IY by decoding the voltage comparison result information stored in the second memory GM2 during the previous suspension period T1.

Furthermore, during the drive period H1 (FIGS. 5 and 6), the sets the value of the adjustment DC current IY in the DC current output circuit DGC2 based on the setting data, and outputs the set value of the adjustment DC current IY to the adjustment terminal Y2.

For example, as shown in FIGS. 5 and 6, in drive period H1, logic circuit Z causes reference voltage setting circuit DREF to output reference voltage VREF such that the value of reference voltage VREF changes stepwise.

Furthermore, for example, as shown in FIGS. 5 and 6, in the drive period H1, the logic circuit Z causes the comparator DT to sequentially compare the reference voltage VREF output by the reference voltage setting circuit DREF with the monitor voltage V1, and output voltage comparison result information (L: low level/H: high level) according to the comparison result.

Then, for example, as shown in FIGS. 5 and 6, during the drive period H1, the logic circuit Z stores the voltage comparison result information output from the comparator DT in the first memory DM1.

For example, as shown in FIG. 5, in a suspension period T2 following a drive period H1 in which the current driver circuit A is stopped, the logic circuit Z transfers the voltage comparison result information stored in the first memory DM1 from the first memory DM1 to the second memory GM2, and stores this voltage comparison result information in the second memory GM2 as voltage comparison result information to be used in the next drive period H2 following the suspension period T2.

Then, the second memory GM2 stores the voltage comparison result information transferred from the first memory DM1, for example, as shown in FIG. 5.

Then, the decoder GDE decodes the voltage comparison result information stored in the second memory GM2 to obtain and output setting data for setting the value of the adjustment DC current IY.

Then, the DC current output circuit DGC2 sets the value of the adjustment DC current IY based on the setting data, for example as shown in FIG. 5, and outputs the set value of the adjustment DC current IY to the adjustment terminal Y2.

In this case, for example, the DC current output circuit DCG2 controls and outputs the adjustment DC current IY based on the setting data indicating the relationship between the reference voltage VREF and the monitor voltage V1 so that the monitor voltage V1 falls within the normal operating range of the current driver circuit A, which is defined by preset upper and lower limit values.

By the operation of the current driver device 200 in the above drive period, the operating point voltage of the current driver circuit A of the current driver device 200 can be controlled within a predetermined operating range (normal operating range), and the decrease in the drive current that drives the load including the capacitor can be suppressed.

In other words, according to the current driver device of the second embodiment, it is possible to suppress the decrease in the drive current that drives a load including a capacitor while controlling the operating point voltage within a predetermined operating range (a range in which normal operation occurs).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A current driver device for supplying a preset drive current to a load including a capacitor via an output terminal, comprising:
a current driver circuit that has an output section connected to the output terminal, that is driven by a power supply voltage and outputs an output AC current from the output section in response to an input AC voltage;
a charging circuit that charges the capacitor of the load and sets the voltage of the output terminal to an initial bias voltage;
a drive current adjustment circuit that detects a monitor voltage, which is an AC voltage generated in the output section of the current driver circuit, and that applies an adjustment DC current to an adjustment terminal between the output section of the current driver circuit and the output terminal based on the detection result of the monitor voltage; and
a control circuit that controls the current driver circuit, the charging circuit, and the drive current adjustment circuit.

2. The current driver device according to claim 1,
wherein the charging circuit includes a switch circuit, wherein the switch circuit is connected between the charging terminal to which the charging voltage is applied and the output terminal, and wherein the switch circuit turns on to establish a conductive state between the charging terminal and the output terminal, or turns off to establish a disconnection state between the charging terminal and the output terminal.

3. The current driver device according to claim 2,
wherein the control circuit turns on the switch circuit during a suspension period before the current driver circuit starts to drive, and charges the capacitor of the load with the charging voltage up to an initial bias voltage, and then, after turning off the switch circuit, the control circuit starts driving the current driver circuit during a drive period.

4. The current driver device according to claim 2,
wherein the charging voltage is a midpoint voltage between the power supply voltage and the ground voltage.

5. The current driver device according to claim 2,
wherein the drive current adjustment circuit comprises:
a detection circuit that detects the waveform of a monitor voltage, which is an AC voltage generated in the output section of the current driver circuit, and outputs the detection result of the waveform of the monitor voltage; and
a DC current adjustment circuit that applies an adjustment DC current to the adjustment terminal between the output section of the current driver circuit and the output terminal, based on the detection result of the waveform of the monitor voltage output by the detection circuit.

6. The current driver device according to claim 3,
wherein the drive current adjustment circuit comprises:
a detection circuit that detects the waveform of a monitor voltage, which is an AC voltage generated in the output section of the current driver circuit, and outputs the detection result of the waveform of the monitor voltage; and
a DC current adjustment circuit that applies an adjustment DC current to the adjustment terminal between the output section of the current driver circuit and the output terminal, based on the detection result of the waveform of the monitor voltage output by the detection circuit.

7. The current driver device according to claim 4,
wherein the drive current adjustment circuit comprises:
a detection circuit that detects the waveform of a monitor voltage, which is an AC voltage generated in the output section of the current driver circuit, and outputs the detection result of the waveform of the monitor voltage; and
a DC current adjustment circuit that applies an adjustment DC current to the adjustment terminal between the output section of the current driver circuit and the output terminal, based on the detection result of the waveform of the monitor voltage output by the detection circuit.

8. The current driver device according to claim 5, wherein the detection circuit comprises:
a peak detection circuit that detects a peak detection voltage corresponding to the peak of the waveform of the monitor voltage;
a bottom detection circuit that detects a bottom detection voltage corresponding to the bottom of the waveform of the monitor voltage;
the DC current adjustment circuit comprises:
a first differential voltage detection circuit that detects a first differential voltage, which is the difference between the peak detection voltage detected by the peak detection circuit and the power supply voltage;
a second differential voltage detection circuit that detects a second differential voltage, which is the difference between the bottom detection voltage detected by the bottom detection circuit and a ground voltage; and
a DC current output circuit that controls the adjustment DC current and outputs the controlled adjustment DC current to the adjustment terminal so that the difference between the first differential voltage and the second differential voltage approaches a preset reference value.

9. The current driver device according to claim 6, wherein the detection circuit comprises:
a peak detection circuit that detects a peak detection voltage corresponding to the peak of the waveform of the monitor voltage; a bottom detection circuit that detects a bottom detection voltage corresponding to the bottom of the waveform of the monitor voltage;
the DC current adjustment circuit comprises:
a first differential voltage detection circuit that detects a first differential voltage, which is the difference between the peak detection voltage detected by the peak detection circuit and the power supply voltage;
a second differential voltage detection circuit that detects a second differential voltage, which is the difference between the bottom detection voltage detected by the bottom detection circuit and a ground voltage; and
a DC current output circuit that controls the adjustment DC current and outputs the controlled adjustment DC current to the adjustment terminal so that the difference between the first differential voltage and the second differential voltage approaches a preset reference value.

10. The current driver device according to claim 7, wherein the detection circuit comprises:
a peak detection circuit that detects a peak detection voltage corresponding to the peak of the waveform of the monitor voltage;
a bottom detection circuit that detects a bottom detection voltage corresponding to the bottom of the waveform of the monitor voltage;
the DC current adjustment circuit comprises:
a first differential voltage detection circuit that detects a first differential voltage, which is the difference between the peak detection voltage detected by the peak detection circuit and the power supply voltage;
a second differential voltage detection circuit that detects a second differential voltage, which is the difference between the bottom detection voltage detected by the bottom detection circuit and a ground voltage; and
a DC current output circuit that controls the adjustment DC current and outputs the controlled adjustment DC current to the adjustment terminal so that the difference between the first differential voltage and the second differential voltage approaches a preset reference value.

11. The current driver device according to claim 8,
wherein the DC current output circuit controls and outputs the adjustment DC current so that the first differential voltage and the second differential voltage are equal.

12. The current driver device according to claim 9,
wherein the DC current output circuit controls and outputs the adjustment DC current so that the first differential voltage and the second differential voltage are equal.

13. The current driver device according to claim 5, further comprising a logic circuit that controls the operation of the detection circuit and the DC current adjustment circuit,
wherein the detection circuit comprises:
a reference voltage setting circuit that sets and outputs one of a plurality of reference voltages, the reference voltage setting circuit outputting the reference voltage so that the value of the reference voltage changes stepwise,
a comparator that sequentially compares the reference voltage output by the reference voltage setting circuit with the monitor voltage and outputs voltage comparison result information according to the comparison result, and
a first memory that stores the voltage comparison result information output by the comparator,
wherein the DC current adjustment circuit comprises:
a second memory that stores the voltage comparison result information transferred from the first memory,
a decoder that obtains and outputs setting data for setting the value of the adjustment DC current by decoding the voltage comparison result information stored in the second memory, and
a DC current output circuit that sets the value of the adjustment DC current based on the setting data and outputs the adjustment DC current of the set value to the adjustment terminal.

14. The current driver device according to claim 6, further comprising a logic circuit that controls the operation of the detection circuit and the DC current adjustment circuit,
wherein the detection circuit comprises:
a reference voltage setting circuit that sets and outputs one of a plurality of reference voltages, the reference voltage setting circuit outputting the reference voltage so that the value of the reference voltage changes stepwise,
a comparator that sequentially compares the reference voltage output by the reference voltage setting circuit with the monitor voltage and outputs voltage comparison result information according to the comparison result, and
a first memory that stores the voltage comparison result information output by the comparator, wherein the DC current adjustment circuit comprises:
a second memory that stores the voltage comparison result information transferred from the first memory,
a decoder that obtains and outputs setting data for setting the value of the adjustment DC current by decoding the voltage comparison result information stored in the second memory, and
a DC current output circuit that sets the value of the adjustment DC current based on the setting data and outputs the adjustment DC current of the set value to the adjustment terminal.

15. The current driver device according to claim 13,
wherein the logic circuit controls the reference voltage setting circuit, the comparator, the first memory, and the second memory, and
wherein, during a drive period in which the current driver circuit is operating, the logic circuit causes the decoder to obtain and output setting data for setting the value of the adjustment DC current by decoding the voltage comparison result information stored in the second memory during the previous suspension period, and causes a DC current output circuit to set the value of the adjustment DC current based on the setting data and output the adjustment DC current of the set value to the adjustment terminal.

16. The current driver device according to claim 14,
wherein the logic circuit controls the reference voltage setting circuit, the comparator, the first memory, and the second memory, and
wherein, during a drive period in which the current driver circuit is operating, the logic circuit causes the decoder to obtain and output setting data for setting the value of the adjustment DC current by decoding the voltage comparison result information stored in the second memory during the previous suspension period, and causes a DC current output circuit to set the value of the adjustment DC current based on the setting data and output the adjustment DC current of the set value to the adjustment terminal.

17. The current driver device according to claim 15,
wherein, during the drive period,
the logic circuit causes the reference voltage setting circuit to output the reference voltage such that the value of the reference voltage changes stepwise,
the logic circuit causes the comparator to sequentially compare the reference voltage output by the reference voltage setting circuit with the monitor voltage and output voltage comparison result information according to the comparison result, and
the logic circuit stores the voltage comparison result information output by the comparator in the first memory.

18. The current driver device according to claim 16,
wherein, during the drive period,
the logic circuit causes the reference voltage setting circuit to output the reference voltage such that the value of the reference voltage changes stepwise,
the logic circuit causes the comparator to sequentially compare the reference voltage output by the reference voltage setting circuit with the monitor voltage and output voltage comparison result information according to the comparison result, and
the logic circuit stores the voltage comparison result information output by the comparator in the first memory.

19. The current driver device according to claim 17,
wherein, during a suspension period following the drive period during which the current driver circuit is stopped,
the logic circuit transfers the voltage comparison result information stored in the first memory from the first memory to the second memory, and stores this voltage comparison result information in the second memory as voltage comparison result information to be used in the next drive period following the suspension period.

20. The current driver device according to claim 18,
wherein, during a suspension period following the drive period during which the current driver circuit is stopped,
the logic circuit transfers the voltage comparison result information stored in the first memory from the first memory to the second memory, and stores this voltage comparison result information in the second memory as voltage comparison result information to be used in the next drive period following the suspension period.
